(19) United States
(12) Patent Application Publication
(10) Pub. No.: US 2025/0280733 A1
(43) Pub. Date: Sep. 4, 2025

(54) SYSTEM AND METHOD FOR PIEZO-POLYMER BASED DETECTION FOR CONNECTION LINE BREAKAGE OR STRAIN

(71) Applicant: Torc Robotics, Inc., Blacksburg, VA (US)

(72) Inventors: Akshay Pai Raikar, Blacksburg, VA (US); Joseph R. Fox-Rabinovitz, Blacksburg, VA (US)

(21) Appl. No.: 18/593,667

(22) Filed: Mar. 1, 2024

(51) Int. Cl. H10N 30/30; B60D 1/64; G01L 5/04; G01L 5/101; H10N 30/00

(52) U.S. Cl. CPC H10N 30/302; B60D 1/64; G01L 5/047; G01L 5/101; H10N 30/702

(57) ABSTRACT

A system for detecting and reporting stress or strain in a connection cable connecting a tractor of a vehicle with a trailer is disclosed. The system includes a connection line breakage/strain detection system including a processor and a memory device storing instructions that when executed by the processor configure the processor to: (i) receive a signal corresponding to an output voltage measured across an electrical circuit, the electrical circuit connected with two ends of a sleeve over a core of the connection cable, the sleeve including a plurality of fibers of piezo polymer material; (ii) identify an extent of stress or strain on the connection cable based upon the received signal; and (iii) in response to the extent of stress or strain on the connection cable meeting a specific threshold condition, generate and transmit an alert or a warning to an external receiver.

### TECHNICAL FIELD

The field of the disclosure relates generally to systems and methods for detecting connection line breakage or strain using piezo polymers.

### BACKGROUND

One element of perception for autonomous vehicles is detection and identification of conditions within or surrounding the autonomous vehicle. During operation, a condition may be detected by the autonomous vehicle that may make further operation of the autonomous vehicle unsafe. For example, a semi-truck may be connected to a trailer through electrical and air hose connections. These connection lines are critical to operation when hauling the trailer. Currently, the hookup of the air hose to the trailer is done manually by the driver at the time of docking to the trailer at a hub. Usually, damage or strain to the air hose is detected through manual inspection. One of the negative outcomes of the damage to this connection cable is that the truck may start bleeding air pressure generated via an auxiliary system on the truck, eventually locking the brakes of both the tractor and trailer until the valve to the air hose is turned off. In an autonomous truck, due to absence of a human driver, such manual inspection check may not be feasible.

Accordingly, there exists a need for systems and methods for detecting excessive strain placed on connection lines and generate an alert such that a preventative action can be taken.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY

In one aspect, a system for detecting and reporting stress or strain in a connection cable connecting a tractor of a vehicle with a trailer is disclosed. The system includes a connection line breakage/strain detection system including a processor and a memory device storing instructions that when executed by the processor configure the processor to: (i) receive a signal corresponding to an output voltage measured across an electrical circuit, the electrical circuit connected with two ends of a sleeve over a core of the connection cable, the sleeve including a plurality of fibers of piezo polymer material; (ii) identify an extent of stress or strain on the connection cable based upon the received signal; and (iii) in response to the extent of stress or strain on the connection cable meeting a specific threshold condition, generate and transmit an alert or a warning to an external receiver.

In another aspect, a method of detecting and reporting stress or strain in a connection cable connecting a tractor of a vehicle with a trailer is disclosed. The method includes (i) receiving a signal corresponding to an output voltage measured across an electrical circuit, the electrical circuit connected with two ends of a sleeve over a core of the connection cable, the sleeve including a plurality of fibers of piezo polymer material; (ii) identifying an extent of stress or strain on the connection cable based upon the received signal; and (iii) in response to the extent of stress or strain on the connection cable meeting a specific threshold condition, generating an alert or a warning.

In yet another aspect, a vehicle is disclosed. The vehicle includes a tractor, a connection cable configured to connect the tractor to a trailer. The connection cable includes a sleeve over a core of the connection cable, and the sleeve includes a plurality of fibers of piezo polymer material. The vehicle includes an electrical circuit connected with two ends of the sleeve, a processor, and a memory device storing instructions that when executed by the processor configure the processor to: (i) receive a signal corresponding to an output voltage measured across the electrical circuit; (ii) identify an extent of stress or strain on the connection cable based upon the received signal; and (iii) in response to the extent of stress or strain on the connection cable meeting a specific threshold condition, generate an alert or a warning corresponding the extent of stress or strain on the connection cable.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a side view of a vehicle including an embodiment of a connection line breakage/strain detection system.

FIG. 2 is a schematic of an autonomy system for use with a vehicle including a connection line breakage/strain detection system.

FIG. 3A illustrates cross-sectional view of a sleeve with piezo-polymer material.

FIG. 3B illustrates a side view of a cable without stress and a side view of a cable with stress.

FIG. 3C illustrates a capacitor-resistor circuit connected with ends of the sleeve shown in FIG. 3A or FIG. 3B.

FIG. 4 is an exemplary flow chart of a method operations of in accordance with embodiments of the present disclosure.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure. The following terms are used in the present disclosure as defined below.

An autonomous vehicle: An autonomous vehicle is a vehicle that is able to operate itself to perform various operations such as controlling or regulating acceleration, braking, or steering wheel positioning, without any human intervention. An autonomous vehicle has an autonomy level of level-4 or level-5 recognized by National Highway Traffic Safety Administration (NHTSA).

A semi-autonomous vehicle: A semi-autonomous vehicle is a vehicle that is able to perform some of the driving related operations such as keeping the vehicle in lane or parking the vehicle without human intervention. A semi-autonomous vehicle has an autonomy level of level-1, level-2, or level-3 recognized by NHTSA. The semi-autonomous vehicle requires a human driver at all times for operating the semi-autonomous vehicle.

A non-autonomous vehicle: A non-autonomous vehicle is a vehicle that is driven by a human driver. A non-autonomous vehicle is neither an autonomous vehicle nor a semi-autonomous vehicle. A non-autonomous vehicle has an autonomy level of level-0 recognized by NHTSA.

Mission control: Mission control, also referenced herein as a centralized or regionalized control, is a hub in communication with one or more autonomous vehicles of a fleet. Database or datastore at mission control may store data received from the autonomous vehicles. Mission control may analyze the stored data and identify information associated with cargo loss events, and issue notifications to others.

When an air hose between a tractor (or cab) and a trailer is strained or damaged, the air hose may leak and lose at least some air pressure. Due to air pressure loss, brakes of both the tractor and trailer may become locked until a valve to the air hose is turned off. Since the autonomous vehicle may not have a human being or driver who can manually inspect for strain or damage to the air hose, various embodiments described in the present disclosure may be used to automatically detect and report strain or damage to the air hose for a corrective action. The embodiments described herein are not limited to an autonomous vehicle only but may be used in a semi-autonomous vehicle or a non-autonomous vehicle as well. Additionally, the embodiments described herein may be applicable to electrical wiring cables.

In some embodiments, a sleeve consisting entirely of a piezo polymer material, or fiber(s) of piezo material may be used to encase the connection, such as the air hose, an electrical cable, etc. By way of a non-limiting example, an air hose or a connection cable may include a sleeve surrounding a core area (which may be hollow central area in case of the air hose, or a solid area carrying electricity or data in case of a cable). The sleeve may include a plurality of fibers or strands of piezo polymer material that changes its resistance value under stress or strain. The change in the resistance value may be used to determine whether the air hose or the connection is strained to an extent requiring an action to prevent further risk of damage during operation of the vehicle. Additionally, or alternatively, upon detecting that the air hose or the connection is strained to an extent that meets a specific threshold condition, the vehicle may be transitioned to a reduced functionality mode. In some embodiments, in addition to the change in the resistance value, a rate of change in the resistance value may also be considered to determine whether transitioning to the reduced functionality mode is appropriate.

In some embodiments, the change in the resistance value may be detected by connecting ends of the sleeve to a capacitor-resistor circuit and monitoring changes in voltage due to strain in the piezo polymer material. When there is excessive strain in cables and connecting wires, the pressure changes on the piezo polymer material encased within the sleeve may cause an increase in the voltage across the sleeve. The voltage across the sleeve may be monitored to determine the strain level on the air hose or connection cable. Additionally, or alternatively, a warning or an alert may be generated by the autonomous system prior to the point that the stress or strain on the air hose or connection cable may cause the vehicle operation to become unsafe. The warning or alert generated by the autonomous system may be transmitted to the mission control for transitioning the autonomous vehicle to the reduced functionality mode.

In some embodiments, another redundant system may be used to determine that the stress or strain on the air hose or connection cable meets the specific threshold condition that requires disconnecting or turning off an air valve. The redundant system may include an engine torque observer that is configured to detect an increase in estimated trailer mass that is caused by locked brakes.

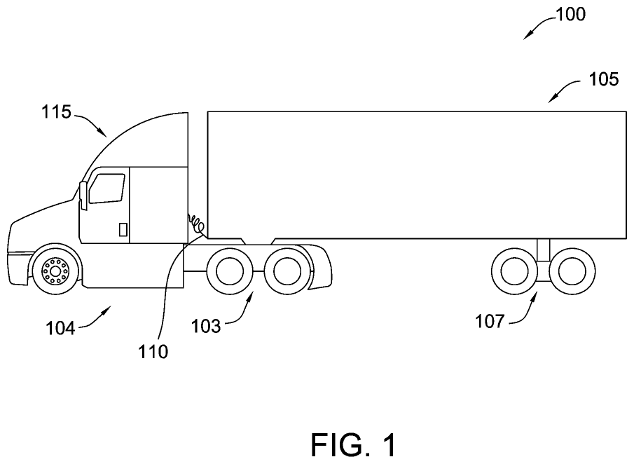

As described herein, the embodiments are described with regards to the autonomous vehicle may also be applicable to a non-autonomous vehicle or a semi-autonomous vehicle. Various features or embodiments described above are discussed in more detail below with respect to FIGS. 1-4.

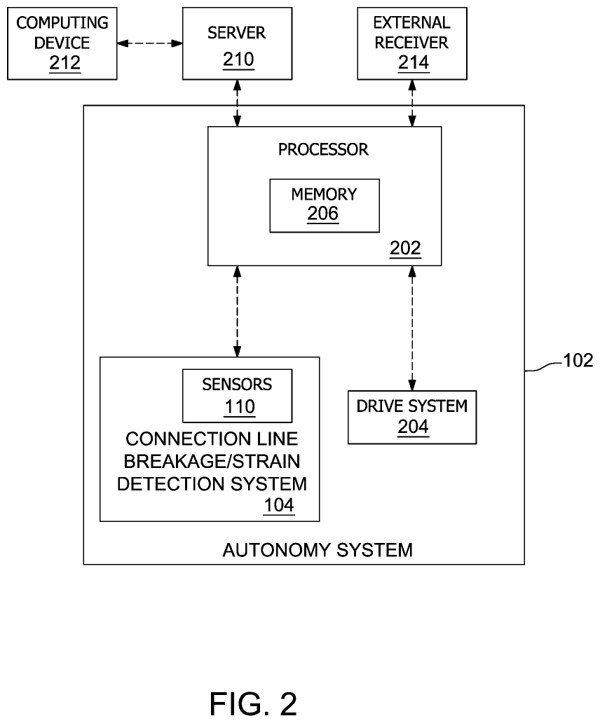

FIG. 1 is a side view of a vehicle 100. The vehicle 100 is configured for autonomous operation via an autonomy system 102 (shown in FIG. 2). The vehicle 100 includes a trailer 105, a tractor 115 connectable to the trailer 105, a front wheel set 103 to support the tractor 115, and a back wheel set 107 to support the trailer 105. The vehicle 100 also includes a connection line breakage/strain detection system 104 for perceiving conditions within or surrounding the vehicle 100, including, but not limited to, stress or strain. The autonomy system 102 may be used to control the vehicle 100 based on the stress or strain detected in an air hose or a cable connection 110 between the trailer 105 and the tractor 115, such as to control movement of the vehicle 100, plan movement of the vehicle 100, turn off an air valve, or transmit a signal to an external receiver, e.g., to mission control to indicate excessive stress or strain to the air hose or connection cable 110.

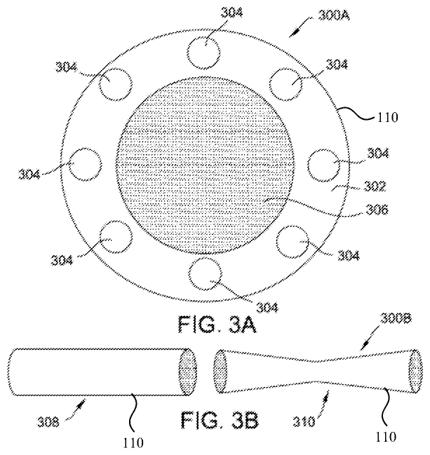

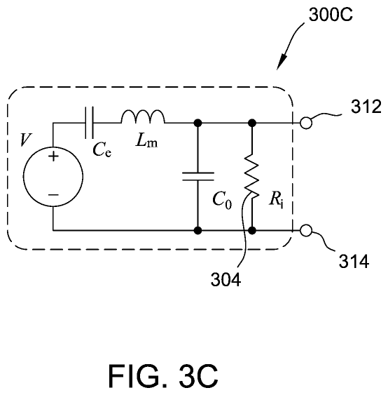

The connection line breakage/strain detection system 104 includes a capacitor-resistor circuit (shown in FIG. 3C) connecting two ends of a sleeve of the air hose or connection cable 110. The sleeve may include fibers or strands of piezo polymer material whose resistance value changes when the air hose or connection cable 110 is under pressure due to stress or strain.

FIG. 2 is a schematic of the autonomy system 102 for use with the vehicle 100. The autonomy system 102 may be used with any embodiment of the connection line breakage/strain detection system 104 as described herein. The autonomy system 102 includes a processor 202 in communication with the connection line breakage/strain detection system. The processor 202 may also be in communication with a drive system 204 to autonomously control movement of the vehicle 100. The processor 202 may be one or more processing systems. The processor 202 includes a memory 206. The memory 206 may be any device allowing information such as executable instructions or data to be stored and retrieved. The processor 202 may include one or more processing units to retrieve and execute instructions and/or data stored by the memory 206. Alternatively, the processor 202 may be coupled with the memory 206, which is not included in the processor 202 or may be independent of the processor 202.

The autonomy system 102 may control the drive system 204 based at least in part upon voltage changes monitored by the capacitor-resistor circuit connecting two ends of the sleeve of the air hose or connection cable 110. Additionally, the autonomy system 102 may use signals received from a server 210 to control the drive system 204, or transmit signals including a warning or an alert to the server 210. The server 210 may be in communication with a computing device 212, such as, but not limited to, a user computing device of a mission control agent, or an artificial intelligence agent. The autonomy system 102 may control operations of the vehicle 100 including transitioning the vehicle 100 to a reduced functionality mode, or disconnecting or turning off an air valve.

FIG. 3A illustrates cross-sectional view 300a of a sleeve 302 with piezo polymer material. The sleeve 302 includes fibers or strands 304 made of piezo polymer material. The piezo polymer material may exhibit a change in its resistance value under pressure due to stress or strain. The sleeve 302 may surround a core 306 that may be a hollow section to carry air. Alternatively, the core 306 may be solid and electrically conductive material carrying electricity or data. In some embodiments, and by way of a non-limiting example, the core 306 may be an optical fiber. The piezo polymer material may include, but is not limited to, polycrystalline ceramic material, lead zirconium titanate, barium titanate, or lead titanate.

FIG. 3B illustrates a side view 300b of an air hose or connection cable 110 including the sleeve 302. The side view 300b illustrates the air hose or connection cable 110 without stress as 308 and with stress as 310. When the air hose of connection cable 110 is under stress as shown in FIG. 3B as 310, the resistance value of the fibers or strands 304 may change, which results in a change in a voltage value measured at a capacitor-resistor circuit 300c shown in FIG. 3C.

The capacitor-resistor circuit 300c may be connected with ends of the sleeve 302 shown in FIG. 3A such that the fibers of strands 304 correspond with a resistor of the capacitor-resistor circuit 300c. Any change in the resistance value of the fibers or strands 304 may cause change in an electric current flowing through the resistor 304 and change in a voltage measured across nodes 312 and 314. Other components (not labeled in FIG. 3C) may be the conventional components of a capacitor-resistor circuit. The change in the voltage or the value of voltage measured across nodes 312 and 314 may be used to identify an extent of stress or strain in the air hose or connection cable 110 and generate a signal including an alert or a warning to report to mission control or take an action by the autonomy system 102. The capacitor-resistor circuit 300c connected with ends of the sleeve 302 may thus form an active piezo sensor or a passive piezo sensor configured to detect an extent of stress or strain on the air hose or connection cable 110.

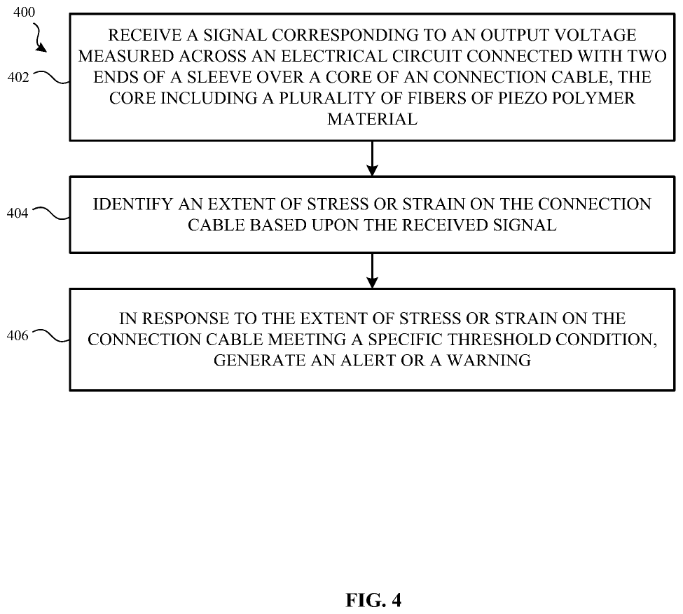

FIG. 4 is an exemplary flow chart 400 of method operations for detecting stress or strain in an air hose or a connection cable, in accordance with embodiments of the present disclosure. The method operations include receiving 402 a signal corresponding to an output voltage measured across an electrical circuit. The electrical circuit is connected with two ends of a sleeve over a core of the connection cable. The sleeve includes a plurality of fibers of piezo polymer material. The connection cable may be an air hose and the core may be hollow carrying air. Alternatively, or additionally, the connection cable may be an electrical cable and the core may include electrically conductive material. By way of a non-limiting example, the electrical circuit may be a capacitor-resistor circuit, and the piezo polymer material may include, but is not limited to only being, polycrystalline ceramic material, lead zirconium titanate, barium titanate, or lead titanate,

The method operations include identifying 404 an extent of stress or strain on the connection cable based upon the received signal. Additionally, or alternatively, based upon the received signal, the vehicle may be transitioned in a reduced functionality mode, when it is determined that the extent of stress or strain on the connection cable meets the specific threshold condition. The method operations include generating 406 an alert or a warning in response to the extent of stress or strain on the connection cable meeting a specific threshold condition. In some embodiments, and by way of a non-limiting example, the vehicle may be transitioned in a reduced functionality mode upon generating or transmitting the alert or warning. The alert of warning may be transmitted to mission control, in some examples.

Some embodiments involve the use of one or more electronic processing or computing devices. As used herein, the terms “processor” and “computer” and related terms, e.g., “processing device,” and “computing device” are not limited to just those integrated circuits referred to in the art as a computer, but broadly refers to a processor, a processing device or system, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory includes non-transitory computer-readable media, which may include, but is not limited to, media such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

What is claimed is:

1. A system for detecting and reporting stress or strain in a connection cable connecting a tractor of a vehicle with a trailer, the system comprising:
a connection line breakage/strain detection system comprising a processor and a memory device, the memory device storing instructions that when executed by the processor configure the processor to:
receive a signal corresponding to an output voltage measured across an electrical circuit, the electrical circuit connected with two ends of a sleeve over a core of the connection cable, the sleeve including a plurality of fibers of piezo polymer material;
identify an extent of stress or strain on the connection cable based upon the received signal; and
in response to the extent of stress or strain on the connection cable meeting a specific threshold condition, generate and transmit an alert or a warning to an external receiver.

2. The system of claim 1, wherein the connection cable is an air hose and the core is hollow carrying air.

3. The system of claim 1, wherein the connection cable is an electrical cable and the core comprises electrically conductive material.

4. The system of claim 1, wherein the electrical circuit is a capacitor-resistor circuit.

5. The system of claim 1, wherein the piezo polymer material comprises polycrystalline ceramic material, lead zirconium titanate, barium titanate, or lead titanate.

6. The system of claim 1, wherein the instructions that when executed by the processor further configure the processor to transition the vehicle in a reduced functionality mode in response to the extent of stress or strain on the connection cable meeting the specific threshold condition.

7. The system of claim 1, wherein the instructions that when executed by the processor further cause the processor to receive a signal to transition the vehicle in a reduced functionality mode upon transmitting the alert or warning to the external receiver.

8. A method of detecting and reporting stress or strain in a connection cable connecting a tractor of a vehicle with a trailer, the method comprising:
receiving a signal corresponding to an output voltage measured across an electrical circuit, the electrical circuit connected with two ends of a sleeve over a core of the connection cable, the sleeve including a plurality of fibers of piezo polymer material;
identifying an extent of stress or strain on the connection cable based upon the received signal; and
in response to the extent of stress or strain on the connection cable meeting a specific threshold condition, generating an alert or a warning.

9. The method of claim 8, wherein the connection cable is an air hose, and the core is hollow carrying air.

10. The method of claim 9, further comprising disconnecting supply of air in response to the extent of stress or strain on the connection cable meeting the specific threshold condition.

11. The method of claim 8, wherein the connection cable is an electrical cable, and the core comprises electrically conductive material.

12. The method of claim 8, wherein the electrical circuit is a capacitor-resistor circuit.

13. The method of claim 8, wherein the piezo polymer material comprises polycrystalline ceramic material, lead zirconium titanate, barium titanate, or lead titanate.

14. The method of claim 8, further comprising transitioning the vehicle in a reduced functionality mode in response to the extent of stress or strain on the connection cable meeting the specific threshold condition.

15. The method of claim 8, further comprising receiving a signal to transition the vehicle in a reduced functionality mode upon transmitting the alert or warning to an external receiver.

16. A vehicle comprising:
a tractor;
a connection cable configured to connect the tractor to a trailer, the connection cable including a sleeve over a core of the connection cable, the sleeve including a plurality of fibers of piezo polymer material;
an electrical circuit connected with two ends of the sleeve;
a processor; and
a memory device, the memory device storing instructions that when executed by the processor configure the processor to:
receive a signal corresponding to an output voltage measured across the electrical circuit;
identify an extent of stress or strain on the connection cable based upon the received signal; and
in response to the extent of stress or strain on the connection cable meeting a specific threshold condition, generate an alert or a warning corresponding the extent of stress or strain on the connection cable.

17. The vehicle of claim 16, wherein the instructions that when executed by the processor further configure the processor to transition the vehicle in a reduced functionality mode in response to the extent of stress or strain on the connection cable meeting the specific threshold condition.

18. The vehicle of claim 16, wherein the instructions that when executed by the processor further configure the processor to receive a signal to transition the vehicle in a reduced functionality mode upon transmitting the alert or warning to an external receiver.

19. The vehicle of claim 16, wherein the connection cable is an air hose and the core is hollow carrying air, and wherein the instructions that when executed by the processor further configure the processor to disconnect supply of air in response to the extent of stress or strain on the connection cable meeting the specific threshold condition.

20. The vehicle of claim 16, wherein the connection cable is an electrical cable, and the core comprises electrically conductive material.
